(19) United States
(12) Patent Application Publication
(10) Pub. No.: US 2023/0317666 A1
(43) Pub. Date: Oct. 5, 2023

(54) SEMICONDUCTOR DEVICE WITH METAL SILICIDE LAYER

(71) Applicant: Infineon Technologies AG, Neubiberg (DE)

(72) Inventors: Gregor Langer, Klagenfurt (AT); Michael Roesner, Villach (AT); Ewald Wiltsche, Maria Saal (AT); Ronny Kern, Finkenstein (AT); Victorina Poenariu, Villach (AT); Axel Koenig, Villach (AT)

(21) Appl. No.: 17/712,738

(22) Filed: Apr. 4, 2022

(51) Int. Cl. H01L 23/00; H01L 29/16

(52) U.S. Cl. CPC H01L 24/27; H01L 29/1608; H01L 2224/27848; H01L 2224/29155; H01L 2924/048; H01L 24/29

(57) ABSTRACT

A semiconductor device and a method of manufacturing a semiconductor are provided. In an embodiment, a method of manufacturing a semiconductor device is provided. A first layer is formed over a silicon carbide (SiC) layer. The first layer has a first surface distal the SiC layer and a second surface proximal the SiC layer. The first layer includes a metal. First thermal energy may be directed to the first surface of the first layer to form a metal silicide layer from the metal of the first layer and silicon of the SiC layer. The metal silicide layer has a first surface distal the SiC layer and a second surface proximal the SiC layer. Second thermal energy may be directed to the first surface of the metal silicide layer to reduce a surface roughness of the first surface of the metal silicide layer

### TECHNICAL FIELD

The present disclosure relates to semiconductor devices.

### BACKGROUND

A semiconductor device may be used in mobile phones, laptops, desktops, tablets, watches, gaming systems, industrial electronics, commercial electronics, and/or consumer electronics. A semiconductor device may comprise an electrical contact between a semiconductor and a metal that may be used to connect a component within the semiconductor device to external circuitry.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

In an embodiment, a method of manufacturing a semiconductor device is provided. A first layer is formed over a silicon carbide (SiC) layer. The first layer has a first surface distal the SiC layer and a second surface proximal the SiC layer. The first layer comprises a metal. First thermal energy may be directed to the first surface of the first layer to form a metal silicide layer from the metal of the first layer and silicon of the SiC layer. The metal silicide layer has a first surface distal the SiC layer and a second surface proximal the SiC layer. Second thermal energy may be directed to the first surface of the metal silicide layer to reduce a surface roughness of the first surface of the metal silicide layer.

In an embodiment, a method of manufacturing a semiconductor device is provided. A first layer is formed over a SiC layer. An electrical contact formation region of the first layer has a first surface distal the SiC layer and a second surface proximal the SiC layer. The first layer comprises a metal. A plurality of laser shots may be performed on the first surface of the electrical contact formation region of the first layer to form a metal silicide layer from the metal of the first layer and silicon of the SiC layer. A laser shot of the plurality of laser shots comprises illuminating a section of the first surface with a laser pulse. Each section of the first surface is illuminated via at least two laser shots of the plurality of laser shots.

In an embodiment, a semiconductor device is provided. The semiconductor device may comprise a SiC layer. The semiconductor device may comprise a metal silicide layer over the SiC layer. The metal silicide layer has a first surface distal the SiC layer and a second surface proximal the SiC layer. A surface roughness of the first surface is at most 200 nanometers. The semiconductor device may comprise one or more metal layers over the metal silicide layer.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1A schematically illustrates acts of manufacturing a semiconductor device according to various examples.

FIG. 1B schematically illustrates an act of manufacturing a semiconductor device according to various examples.

FIG. 1C schematically illustrates an act of manufacturing a semiconductor device according to various examples.

FIG. 1D schematically illustrates an act of manufacturing a semiconductor device according to various examples.

FIG. 1E schematically illustrates an act of manufacturing a semiconductor device according to various examples.

FIG. 2 is an illustration of an example method in accordance with the techniques presented herein.

FIG. 3A schematically illustrates performing laser shots on a top surface of a layer according to various examples.

FIG. 3B schematically illustrates performing laser shots on a top surface of a layer according to various examples.

FIG. 3C schematically illustrates performing laser shots on a top surface of a layer according to various examples.

FIG. 4A schematically illustrates performing laser shots on a top surface of a layer according to various examples.

FIG. 4B schematically illustrates performing laser shots on a top surface of a layer according to various examples.

FIG. 5 is an illustration of an example method in accordance with the techniques presented herein.

FIG. 6 schematically illustrates acts of manufacturing a semiconductor device according to various examples.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

The term “over” and/or “overlying” is not to be construed as meaning only “directly over” and/or “having direct contact with”. Rather, if one element is “over” and/or “overlying” another element (e.g., a region is overlying another region), a further element (e.g., a further region) may be positioned between the two elements (e.g., a further region may be positioned between a first region and a second region if the first region is “over” and/or “overlying” the second region). Further, if a first element is “over” and/or “overlying” a second element, at least some of the first element may be vertically coincident with the second element, such that a vertical line may intersect the first element and the second element.

The semiconductor substrate or body may extend along a main extension plane. The term “horizontal” as used in this specification intends to describe an orientation substantially parallel to said main extension plane. A first or main horizontal side of the semiconductor substrate or body may run substantially parallel to horizontal directions or may have surface sections that enclose an angle of at most 8° (or at most 6°) with the main extension plane. The first or main horizontal side can be for instance the surface of a wafer or a die. Sometimes, the horizontal direction is also referred to as lateral direction.

The term “vertical” as used in this specification intends to describe an orientation which is substantially arranged perpendicular to the horizontal direction, (e.g., parallel to the normal direction of the first side of the semiconductor substrate or body or parallel to the normal direction of a surface section of the first side of the semiconductor substrate or body).

A semiconductor device may comprise an electrical contact (e.g., an Ohmic contact) between a semiconductor and a metal. The electrical contact may be formed using a metal silicide layer between the semiconductor and the metal. A surface of the metal silicide layer may have a first surface roughness and/or may have protrusions (e.g., local peaks in elevation of the metal silicide layer, such as bumps, hills and/or hillocks). A surface roughness and/or protrusions of a surface (e.g., back side surface) of the metal depend upon the surface roughness and/or the protrusions of the surface of the metal silicide layer. For example, the metal silicide layer having a higher surface roughness and/or larger protrusions may result in the surface of the metal having a higher surface roughness and/or larger protrusions. In some examples, the surface of the metal may be electrically connected to a component, such as at least one of a measuring chuck for wafer testing, a lead frame, etc. Higher surface roughness and/or larger protrusions of the surface may reduce a conductivity of the electrical connection between the metal and the component, such as due to increased voids between the metal and the component.

In accordance with the present disclosure, a semiconductor device and a method of manufacturing the semiconductor device are provided. The semiconductor device may comprise a metal silicide layer. In some examples, a surface of the metal silicide layer may have a lower surface roughness, smaller and/or shorter protrusions of the metal silicide layer, and/or a reduced quantity of protrusions. In some examples, the metal silicide layer may be formed from a semiconductor layer (e.g., a silicon carbide (SiC) layer) and a first layer, overlying the semiconductor layer, comprising a metal. In an example, first thermal energy may be directed to a surface of the first layer to form the metal silicide layer from the metal of the first layer and silicon of the semiconductor layer. Second thermal energy may be directed to a surface of the metal silicide layer to reduce the surface roughness of the top surface of the metal silicide layer. The second thermal energy may reduce a quantity, size and/or height of protrusions of the surface of the metal silicide layer. One or more metal layers may be formed over the metal silicide layer (e.g., the metal silicide layer may provide an electrical contact between the one or more metal layers and the semiconductor layer). The reduced surface roughness of the surface, and/or the reduced quantity, size and/or height of protrusions of the surface may provide for an improved electrical contact (e.g., Ohmic contact) between the one or more metal layers and the semiconductor layer, and/or higher conductivity between the one or more metal layers and a component connected to the one or more metal layers, thereby providing for improved operation and/or performance of the semiconductor device.

In an embodiment of the presently disclosed embodiments, a method of manufacturing a semiconductor device is provided. The method may comprise forming a first layer over a semiconductor layer, such as a semiconductor substrate. In some examples, the semiconductor layer is a SiC layer, such as a SiC substrate. In some examples, the first layer has a first surface distal the SiC layer and a second surface proximal the SiC layer. The first layer comprises a metal. In some examples, the metal comprises nickel, titanium, tantalum, tungsten, molybdenum, nickel aluminide (NiAl), titanium nitride (TiN), tantalum nitride (TaN), molybdenum nitride (MoN), tungsten nitride (WN) and/or other metal.

The method may comprise directing first thermal energy to the first surface of the first layer to form a metal silicide layer from the metal of the first layer and silicon of the semiconductor layer. The first thermal energy being directed to the first surface of the first layer melts metal of the first layer and/or causes a silicidation reaction between the metal and silicon of the semiconductor layer to occur. In some examples, a measuring device may be used to perform one or more measurements indicative of whether or not metal of the first layer is sufficiently melted by thermal energy of the first thermal energy. In some examples, based upon a determination that metal of the first layer is not sufficiently melted by the thermal energy, further thermal energy of the first thermal energy may be directed to the first surface of the first layer. In some examples, the first thermal energy comprises energy, introduced to the first layer and/or the semiconductor layer, via a laser that illuminates at least a portion of the first surface of the first layer. For example, the laser may comprise a laser pulse output by a laser source. In some examples, the first thermal energy may comprise energy, introduced to the first layer and/or the semiconductor layer, via multiple laser pulses (e.g., the multiple laser pulses may be output by the laser source to illuminate different sections of the first surface of the first layer). Alternatively and/or additionally, the laser may comprise a continuous laser output by the laser source.

The metal silicide layer has a first surface distal the SiC layer and a second surface proximal the SiC layer. The method may comprise directing second thermal energy to the first surface of the metal silicide layer. The second thermal energy being directed to the first surface of the metal silicide layer melts (e.g., re-melts) metal of the metal silicide layer. In some examples, the second thermal energy comprises energy, introduced to the metal silicide layer and/or the semiconductor layer, via a laser that illuminates at least a portion of the first surface of the metal silicide layer. For example, the laser may comprise a laser pulse output by a laser source. In some examples, the first thermal energy may comprise energy, introduced to the metal silicide layer and/or the semiconductor layer, via multiple laser pulses (e.g., the multiple laser pulses may be output by the laser source to illuminate different sections of the first surface of the metal silicide layer). Alternatively and/or additionally, the laser may comprise a continuous laser output by the laser source.

In some examples, prior to directing the second thermal energy to the first surface of the metal silicide layer, the first surface of the metal silicide layer has a first surface roughness. After directing the second thermal energy to the first surface of the metal silicide layer, the first surface of the metal silicide layer has a second surface roughness. The second surface roughness is lower than the first surface roughness (e.g., directing the second thermal energy to the first surface of the metal silicide layer reduces the surface roughness of the first surface). For example, directing the second thermal energy to the first surface of the metal silicide layer smoothens the first surface of the metal silicide layer.

Alternatively and/or additionally, prior to directing the second thermal energy to the first surface of the metal silicide layer, the first surface of the metal silicide layer may have a first quantity of protrusions (e.g., local peaks in elevation of the metal silicide layer, such as bumps, hills and/or hillocks). In some examples, after directing the second thermal energy to the first surface of the metal silicide layer, the first surface of the metal silicide layer has a second quantity of protrusions. The second quantity of protrusions may be less than the first quantity of protrusions (e.g., directing the second thermal energy to the first surface of the metal silicide layer reduces the quantity of protrusions of the first surface). Alternatively and/or additionally, protrusions of the first surface of the metal silicide layer prior to directing the second thermal energy to the first surface of the metal silicide layer may be larger and/or taller as compared to protrusions of the first surface after directing the second thermal energy to the first surface of the metal silicide layer (e.g., directing the second thermal energy to the first surface of the metal silicide layer reduces the size and/or height of protrusions of the first surface).

In some examples, a duration of time between a first time when the first thermal energy is directed to the first surface of the first layer and a second time when the second thermal energy is directed to the first surface of the metal silicide layer is at least a threshold duration of time. In an example, the first thermal energy melts metal of the first layer to form melted metal, wherein the threshold duration of time is based upon a solidification time of the melted metal. The solidification time corresponds to a time it takes for the melted metal to solidify. In some examples, the solidification time depends upon one or more properties of the metal, an energy level of the first thermal energy and/or an amount of time it takes for energy of the first thermal energy introduced to the melted metal to dissipate. In an example, the threshold duration of time is equal to or larger than the solidification time such that the melted metal solidifies prior to the second time when the second thermal energy is directed to the first surface of the metal silicide layer. The threshold duration of time may be in the range of at least 3 milliseconds to at most 1000 milliseconds, and/or in the range of at least 3 milliseconds to at most 333 milliseconds.

In some examples, the first layer comprises silicon. The silicon may suppress carbon release during formation of the metal silicide layer. For example, carbon from the semiconductor layer (e.g., the SiC layer) may defuse into the metal silicide layer during formation of the metal silicide layer. In an example, carbon clusters may form within the metal silicide layer and/or a carbon layer may form on the first surface of the metal silicide layer. Including silicon in the first layer may reduce the amount of carbon present in the metal silicide layer.

The method may comprise forming one or more metal layers over the metal silicide layer after the second thermal energy is directed to the first surface of the metal silicide layer. The method may comprise affixing a metal layer, of the one or more metal layers, to a lead frame. In some examples, the metal layer is soldered to the lead frame. The metal silicide layer may provide an electrical contact (e.g., Ohmic contact) between the semiconductor layer and the one or more metal layers.

In some examples, the first layer is formed to have a thickness of less than 200 nanometers. The thickness of the first layer may be in the range of at least 10 nanometers to at most 200 nanometers, in the range of at least 10 nanometers to at most 100 nanometers, and/or in the range of at least 10 nanometers to at most 30 nanometers. In a first scenario, the thickness of the first layer may be in the range of at least 10 nanometers to at most 30 nanometers. In a second scenario, the thickness of the first layer may be larger than or equal to 40 nanometers. A surface roughness of the first surface of the metal silicide layer formed in the first scenario may be lower than a surface roughness of the first surface of the metal silicide layer formed in the second scenario. Alternatively and/or additionally, protrusions of the first surface of the metal silicide layer formed in the first scenario may be smaller and/or shorter than protrusions of the first surface of the metal silicide layer formed in the second scenario.

In an embodiment of the presently disclosed embodiments, a method of manufacturing a semiconductor device is provided. The method may comprise forming a first layer over a semiconductor layer, such as a semiconductor substrate. In some examples, the semiconductor layer is a SiC layer, such as a SiC substrate.

In some examples, an electrical contact formation region of the first layer has a first surface distal the semiconductor layer and a second surface proximal the semiconductor layer. The first layer comprises a metal. In some examples, the metal comprises nickel, titanium, tantalum, tungsten, molybdenum, NiAl, TiN, TaN, MoN, WN and/or other metal. In some examples, the electrical contact formation region of the first layer corresponds to a region, of the first layer, from which a metal silicide layer is formed to form an electrical contact (e.g., Ohmic contact) between the semiconductor layer and one or more metals.

In a first example, the electrical contact formation region comprises an entirety of the first layer. In the example, the first surface of the electrical contact formation region is a surface of the first layer.

In a second example, the electrical contact formation region comprises a portion of the first layer. In the example, the first surface of the electrical contact formation region is portion of a surface of the first layer.

The method may comprise performing a plurality of laser shots on the first surface of the electrical contact formation region of the first layer to form a metal silicide layer from the metal of the first layer and silicon of the semiconductor layer. A laser shot of the plurality of laser shots (and/or each laser shot of the plurality of laser shots) comprises illuminating a section of the first surface with a laser pulse. Each section of the first surface is illuminated via at least two laser shots of the plurality of laser shots.

In some examples, the plurality of laser shots comprise a first laser shot and a second laser shot. The first laser shot comprises illuminating a first section of the first surface with a first laser pulse. The second laser shot comprises illuminating the first section of the first surface with a second laser pulse. A duration of time between the first laser shot and the second laser shot is at least a threshold duration of time.

In some examples, the first laser shot melts metal of the first layer to form melted metal, wherein the threshold duration of time is based upon a solidification time of the melted metal (e.g., a time it takes for the melted metal to solidify). In some examples, the solidification time depends upon one or more properties of the metal, an energy level of the first laser pulse and/or an amount of time it takes for energy of the first laser pulse introduced to the melted metal to dissipate. In an example, the threshold duration of time is equal to or larger than the solidification time such that the melted metal solidifies prior to the second laser shot. The threshold duration of time may be in the range of at least 3 milliseconds to at most 1000 milliseconds, and/or in the range of at least 3 milliseconds to at most 333 milliseconds.

In some examples, after the first laser shot and prior to the second laser shot, the first section of the first surface has a first surface roughness. After the second laser shot, the first section of the first surface has a second surface roughness. The second surface roughness is lower than the first surface roughness (e.g., performing the second laser shot reduces the surface roughness of the first section of the first surface). For example, directing the performing the second laser shot smoothens the first section of the first surface.

Alternatively and/or additionally, after the first laser shot and prior to the second laser shot, the first section of the first surface may have a first quantity of protrusions. In some examples, after the second laser shot, the first section of the first surface has a second quantity of protrusions. The second quantity of protrusions may be less than the first quantity of protrusions (e.g., performing the second laser shot reduces the quantity of protrusions of the first section of the first surface). Alternatively and/or additionally, protrusions of the first section of the first surface of the metal silicide layer prior to the second laser shot may be larger and/or taller as compared to protrusions of the first section of the first surface after the second laser shot (e.g., performing the second laser shot reduces the size and/or height of protrusions of the first section of the first surface).

In some examples, the first laser pulse illuminates a second section of the first surface comprising the first section of the first surface. The second laser pulse illuminates a third section of the first surface comprising the first section of the first surface. The third section of the first surface is offset from the second section of the first surface. The third section and the second section overlap at the first section.

In some examples, the first layer is formed to have a thickness of less than 200 nanometers. The thickness of the first layer may be in the range of at least 10 nanometers to at most 200 nanometers, in the range of at least 10 nanometers to at most 100 nanometers, and/or in the range of at least 10 nanometers to at most 30 nanometers.

In some examples, the first layer comprises silicon. The silicon may suppress carbon release during formation of the metal silicide layer.

The method may comprise forming one or more metal layers over the metal silicide layer after the plurality of laser shots are performed. The method may comprise affixing a metal layer, of the one or more metal layers, to a lead frame. The metal layer may be soldered to the lead frame.

In an embodiment of the presently disclosed embodiments, a semiconductor device is provided. The semiconductor device may comprise a semiconductor layer, such as a semiconductor substrate. In some examples, the semiconductor layer is a SiC layer, such as a SiC substrate. The semiconductor device may comprise a metal silicide layer over the semiconductor layer. The metal silicide layer has a first surface distal the semiconductor layer and a second surface proximal the semiconductor layer. A surface roughness of the first surface is at most 200 nanometers. The semiconductor device may comprise one or more metal layers over the metal silicide layer. The surface roughness may correspond to a mean surface roughness of the first surface (e.g., a surface roughness averaged over the first surface). For example, an average vertical extension of protrusions and/or valleys of the first surface may be at most 200 nanometers (e.g., the average vertical extension may correspond to an average of vertical extensions of the protrusions and/or the valleys of the first surface).

In some examples, a thickness of the metal silicide layer is less than 300 nanometers.

In some examples, the metal comprises nickel, titanium, tantalum, tungsten, molybdenum, NiAl, TiN, TaN, MoN, WN and/or other metal.

In some examples, a metal layer, of the one or more metal layers, is affixed to a lead frame. The metal layer may be soldered to the lead frame.

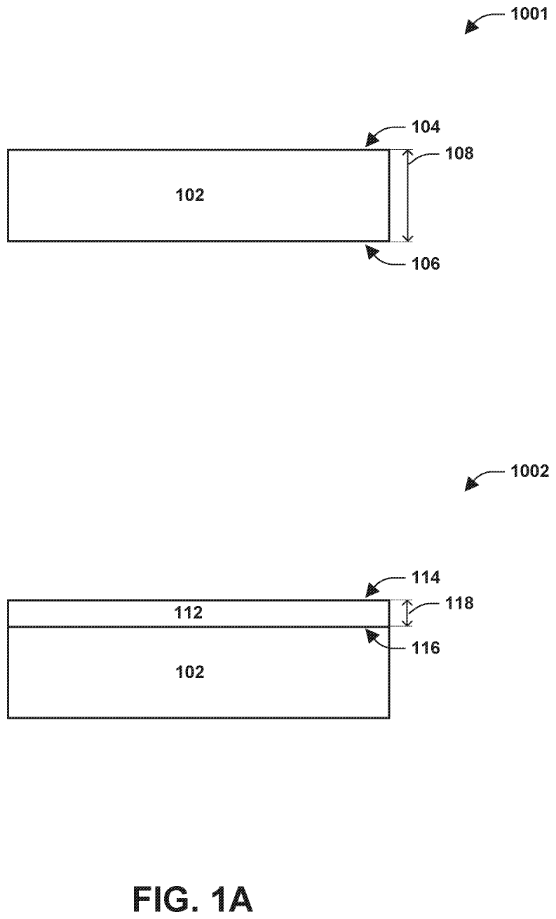

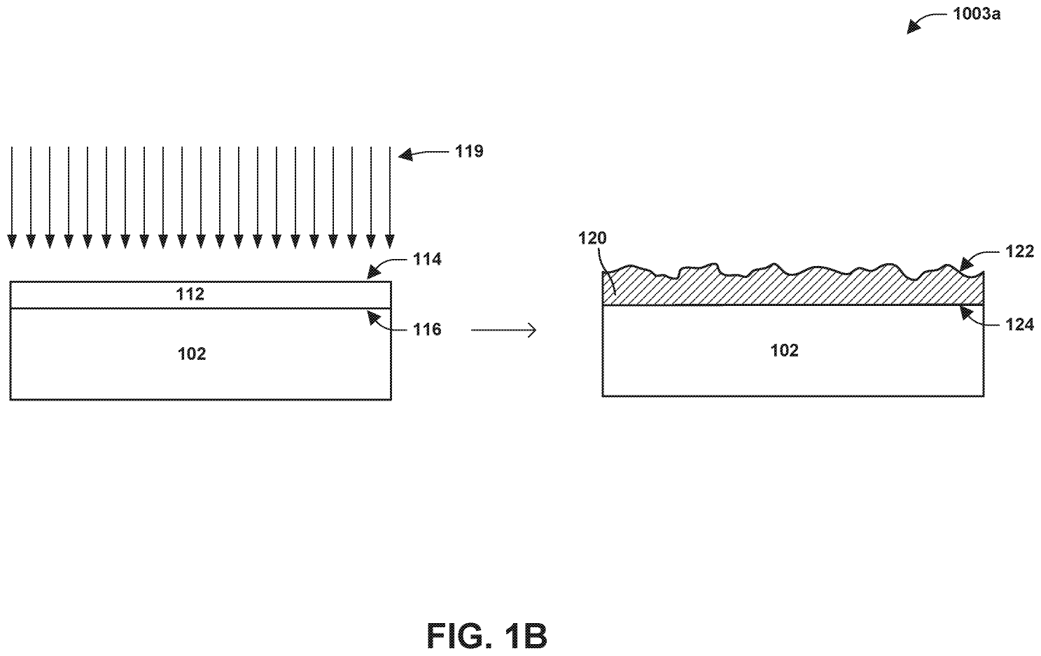

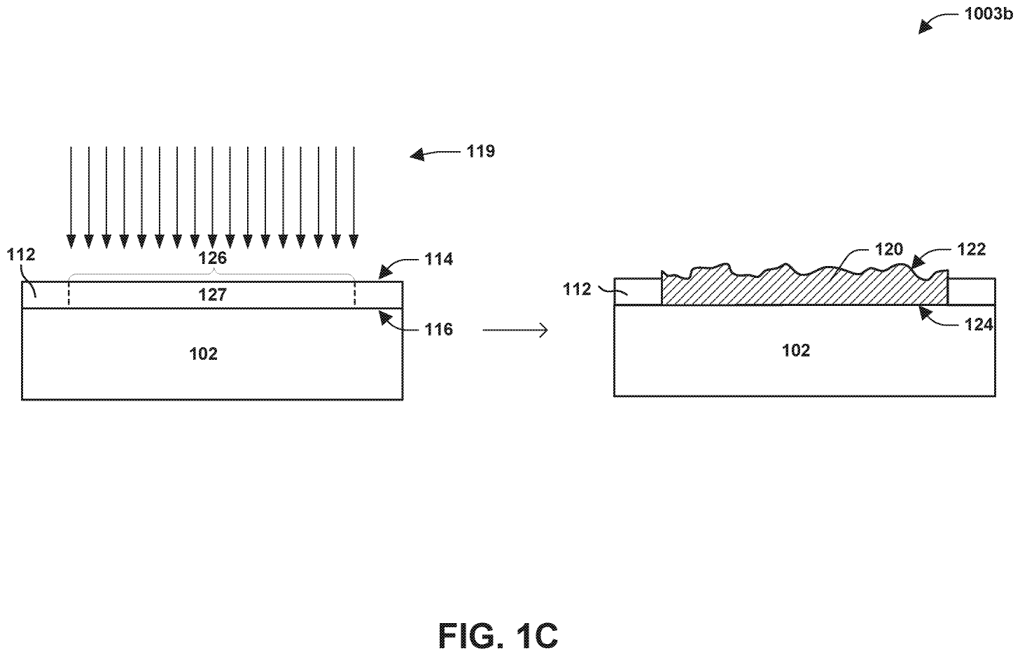

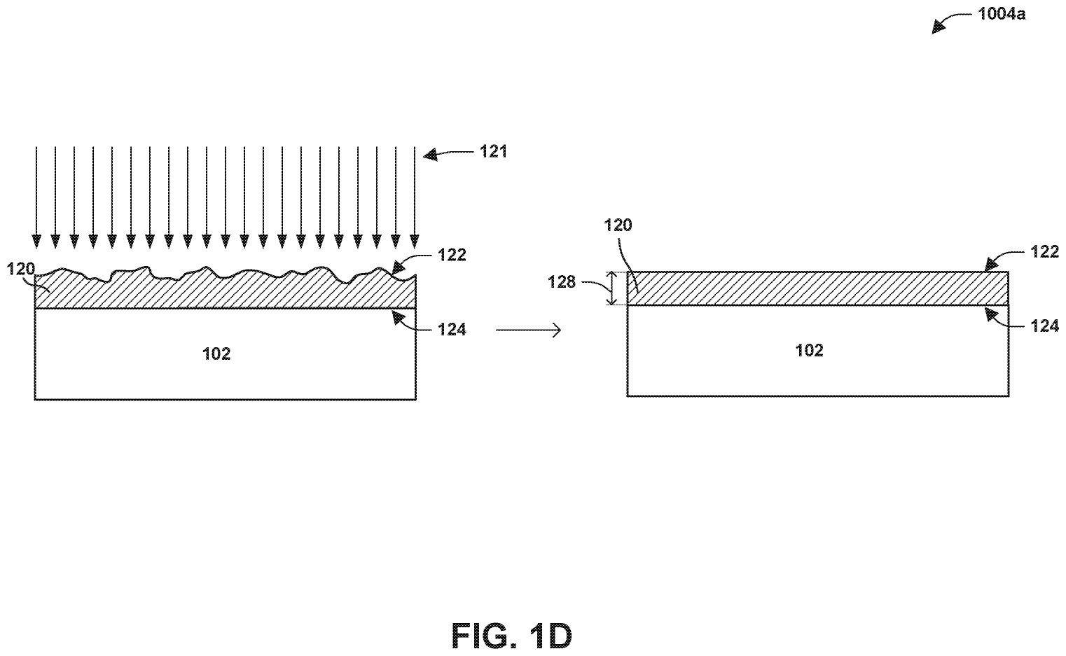

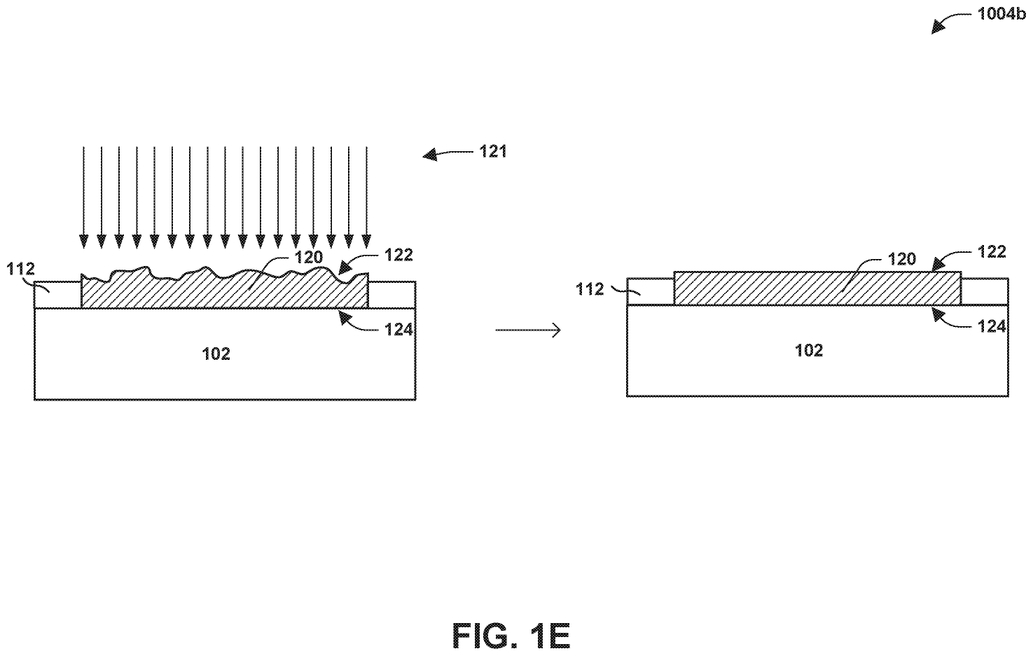

FIGS. 1A-1E illustrate aspects with respect to manufacturing a semiconductor device according to various examples of the present disclosure. At 1001 (illustrated in FIG. 1A), a semiconductor layer 102 is provided. The semiconductor layer 102 may comprise crystalline semiconductor material. The semiconductor layer 102 may comprise a semiconductor element (e.g., silicon, germanium, and/or other semiconductor element) and/or a semiconductor compound (e.g., SiC, silicon germanium (SiGe), gallium arsenide (GaAs), gallium nitride (GaN) and/or other semiconductor compound). The semiconductor layer 102 may comprise dopants (e.g., nitrogen (N), phosphorus (P), beryllium (Be), boron (B), aluminum (Al), gallium (Ga) and/or other dopants). Alternatively and/or additionally, the semiconductor layer 102 may comprise impurities (e.g., hydrogen, fluorine, oxygen and/or other impurities). In some examples, the semiconductor layer 102 is a semiconductor substrate, such as a SiC substrate. A thickness 108 of the semiconductor layer 102 may be in the range of at least 10 micrometers to at most 500 micrometers, in the range of at least 50 micrometers to at most 200 micrometers, and/or in the range of at least 80 micrometers to at most 140 micrometers. The semiconductor layer 102 has a first surface 104 and a second surface 106 opposite the first surface 104. In some examples, the first surface 104 corresponds to a back side of the semiconductor layer 102 (e.g., a wafer back side). In some examples, the second surface 106 corresponds to a front side of the semiconductor layer 102 (e.g., a wafer front side).

At 1002 (illustrated in FIG. 1A), a first layer 112 is formed over the semiconductor layer 102. The first layer 112 comprises a metal. In some examples, the metal comprises nickel, titanium, tantalum, tungsten, molybdenum, NiAl, TiN, TaN, MoN, WN and/or other metal. The first layer 112 may overlie the semiconductor layer 102. In some examples, the first layer 112 may comprise a non-metal (in addition to the metal, for example), such as silicon, for suppression of carbon release during metal silicide formation from the first layer 112 and the semiconductor layer 102. In an example, the first layer 112 comprises nickel and silicon, wherein the nickel may be present in the range of at least 2 weight % to at most 95 weight %, the range of at least 2 weight % to at most 50 weight %, the range of at least 6 weight % to at most 16 weight %, and/or the range of at least 10 weight % to at most 12 weight %. The first layer 112 has a first surface 114 distal the semiconductor layer 102 and a second surface 116 proximal the semiconductor layer 102. In some examples, the first surface 114 of the first layer 112 may be adjacent to and/or may be in contact (e.g., direct contact) with the first surface 104 of the semiconductor layer 102. In some examples, the first layer 112 is formed via a sputtering process comprising sputtering the first layer 112 on the first surface 104 of the semiconductor layer 102. In some examples, the first layer 112 has a thickness 118 of less than 200 nanometers. The thickness 118 of the first layer 112 may be in the range of at least 10 nanometers to at most 200 nanometers, in the range of at least 10 nanometers to at most 100 nanometers, and/or in the range of at least 10 nanometers to at most 30 nanometers.

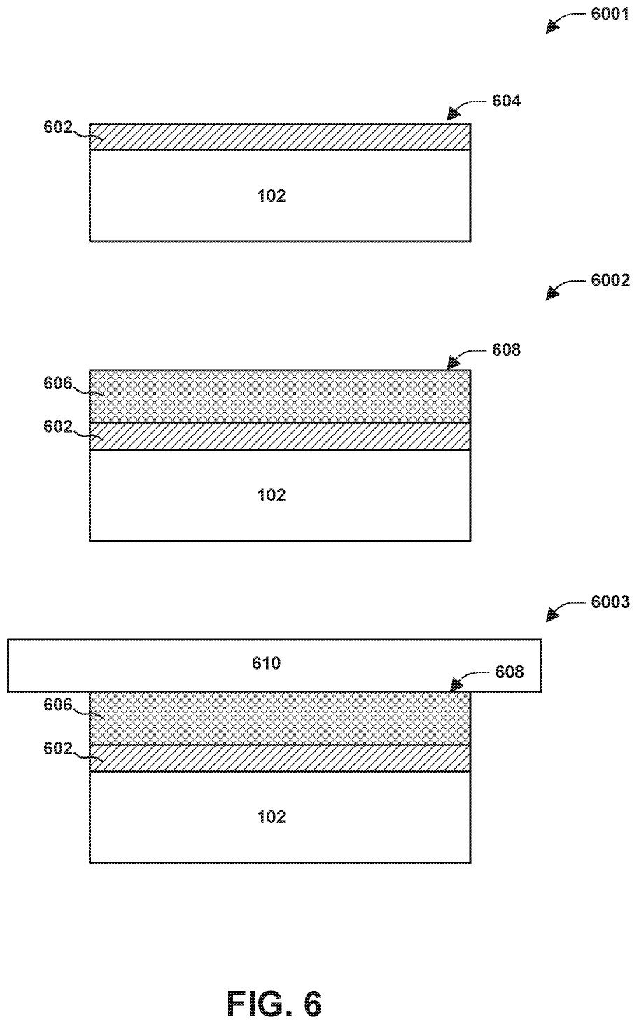

At 1003 (examples of which are illustrated in FIGS. 1B-1C), first thermal energy 119 is directed to the first surface 114 of the first layer 112 to form a metal silicide layer 120 from the metal of the first layer 112 and silicon of the semiconductor layer 102. The metal silicide layer 120 has a first surface 122 distal the semiconductor layer 102 and a second surface 124 proximal the semiconductor layer 102. In some examples, the metal silicide layer 120 forms an electrical contact, such as an ohmic contact, between the semiconductor layer 102 and one or more metal layers (e.g., one or more metal layers 606 shown in FIG. 6). For example, the metal silicide layer 120 may provide a connection between external circuitry and one or more components disposed in the semiconductor device, such as one or more components embedded in the semiconductor layer 102. In some examples, the one or more components disposed in the semiconductor device comprises a transistor comprising an insulated-gate bipolar transistor (IGBT), a field-effect transistor (FET), a metal-oxide-semiconductor FET (MOSFET) and/or other type of transistor. In an example, the electrical contact may be connected to and/or may correspond to a drain of the transistor, such as a drain of a MOSFET. In some examples, the one or more components disposed in the semiconductor device comprises a diode, wherein the electrical contact may be connected to and/or may correspond to an electrode of the diode.

FIG. 1B illustrates an example 1003a of the act 1003 in which the first thermal energy 119 is directed to an entirety of the first surface 114 of the first layer 112.

FIG. 1C illustrates an example 1003b of the act 1003 in which the first thermal energy 119 is directed to a portion 126 of the first surface 114 of the first layer 112. In some examples, the portion 126 of the first surface 114 corresponds to a top surface of an electrical contact formation region 127 of the first layer 112. In some examples, the electrical contact formation region 127 of the first layer 112 corresponds to a region, of the first layer 112, from which the metal silicide layer 120, is formed to form an electrical contact. In some examples, such as shown in FIG. 1C, the electrical contact formation region 127 may be merely a portion of the first layer 112. In some examples, such as shown in FIG. 1B, the electrical contact formation region 127 may comprise an entirety of the first layer 112.

In some examples, the first thermal energy 119 is directed to the first surface 114 of the first layer 112 to heat at least a portion of the first layer 112 and/or at least a portion of the semiconductor layer 102 to a first temperature, wherein the first temperature may be in the range of at least 900° Celsius to at most 1300° Celsius, in the range of at least 950° Celsius to at most 1100° Celsius, and/or in the range of at least 970° Celsius to at most 1010° Celsius. The first thermal energy 119 being directed to the first surface 114 of the first layer 112 melts metal of the first layer 112 and/or causes a silicidation reaction to occur. In an example in which the first layer 112 comprises nickel and the semiconductor layer 102 comprises SiC, the silicidation reaction may comprise SiC+2Ni→Ni₂Si+C. Alternatively and/or additionally, in an example in which the first layer 112 comprises nickel and the semiconductor layer 102 comprises SiC, the metal silicide layer 120 comprises at least one of Ni₂Si, Ni₃₁Si₁₂, Ni₃Si, etc.

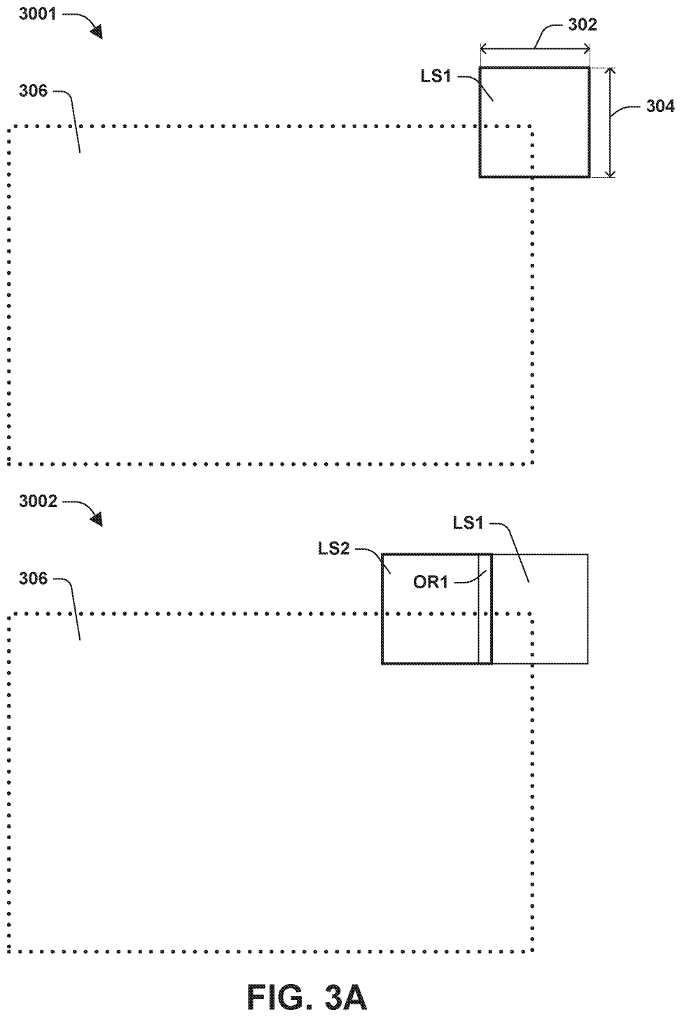

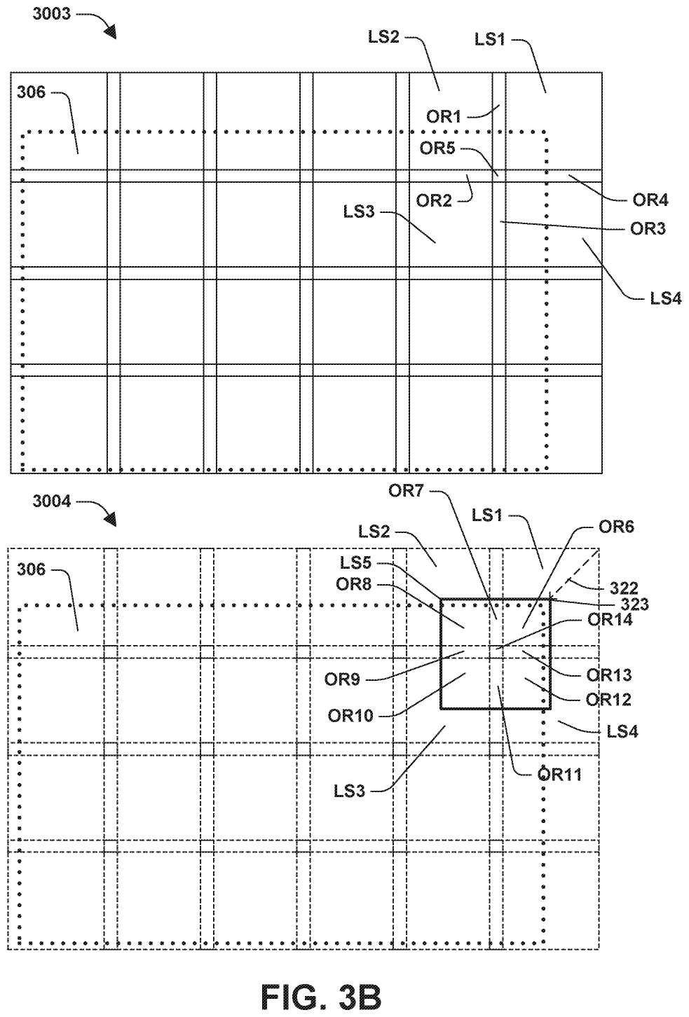

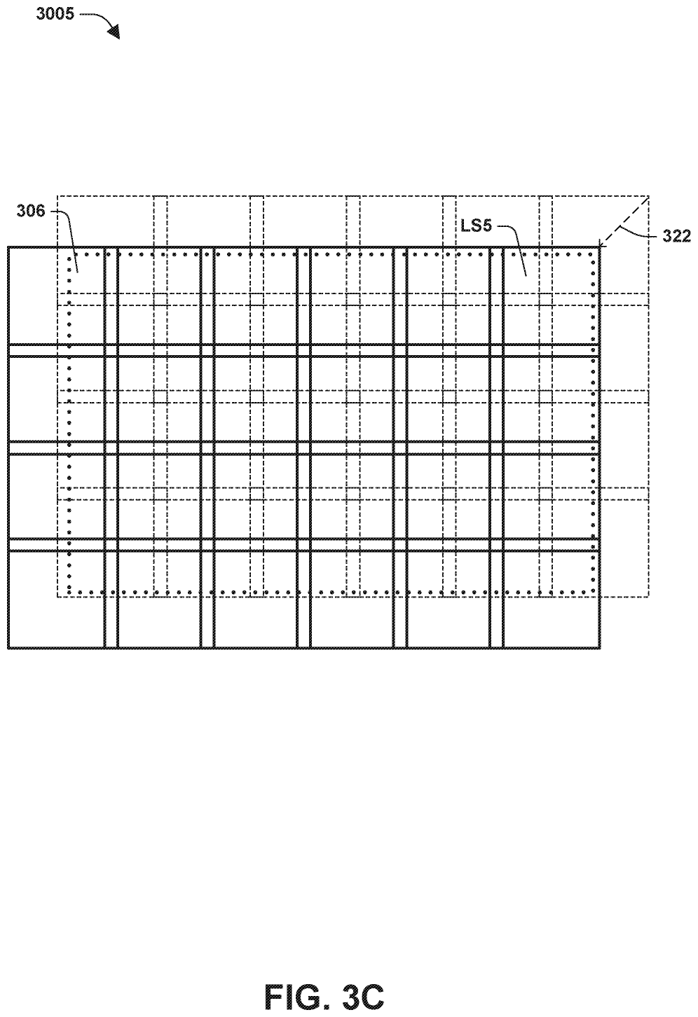

In some examples, act 1003 is performed such that one or more portions of the semiconductor device are not heated to the first temperature. In an example, the first thermal energy 119 may be directed to the first surface 114 of the first layer 112 such that the silicidation reaction occurs without damaging one or more components disposed in the one or more portions of the semiconductor device (e.g., the first thermal energy 119 may be localized to a first portion of the semiconductor device to cause the silicidation reaction, wherein the first portion may comprise at least some of the first layer 112 and/or at least some of the semiconductor device). In some examples, the one or more portions of the semiconductor device may comprise a portion of the semiconductor layer 102 proximal the second surface 106 of the semiconductor layer 102 (e.g., the one or more components are disposed in the portion of the semiconductor layer 102). In an example, act 1003 comprises performing one or more laser shots on the first surface 114 of the first layer 112, such as one or more laser shots of a laser thermal annealing (LTA) process (e.g., the one or more laser shots may comprise the first plurality of laser shots shown in and/or described with respect to FIGS. 3A-3C).

At 1004 (examples of which are illustrated in FIGS. 1D-1E), second thermal energy 121 is directed to the first surface 122 of the metal silicide layer 120 to reduce a surface roughness of the first surface 122 of the metal silicide layer 120. In some examples, a thickness 128 (shown in FIG. 1D) of the metal silicide layer 120 is less than 300 nanometers (e.g., the thickness 128 may be larger than the thickness 118 of the first layer 112).

FIG. 1D illustrates an example 1004a of the act 1004 in which the act 1004 is performed after the example 1003a (shown in FIG. 1B) of the act 1003 is performed. FIG. 1E illustrates an example 1004b of the act 1004 in which the act 1004 is performed after the example 1003b (shown in FIG. 1C) of the act 1003 is performed.

In some examples, the second thermal energy 121 is directed to the first surface 122 of the metal silicide layer 120 to heat at least a portion of the metal silicide layer 120 to a second temperature, wherein the second temperature may be in the range of at least 900° Celsius to at most 1300° Celsius, in the range of at least 950° Celsius to at most 1100° Celsius, and/or in the range of at least 970° Celsius to at most 1010° Celsius. In some examples, the second temperature is about the same as the first temperature. In some examples, the second thermal energy 121 being directed to the first surface 122 of the metal silicide layer 120 melts metal of the metal silicide layer 120.

In some examples, act 1004 is performed such that the one or more portions of the semiconductor device are not heated to the second temperature. For example, the second thermal energy 121 may be directed to the first surface 122 of the metal silicide layer 120 such that a second portion of the semiconductor device (e.g., the second portion may comprise the metal silicide layer 120 and/or at least some of the semiconductor device) is heated without damaging one or more components disposed in the one or more portions of the semiconductor device (e.g., the second thermal energy 121 may be localized to the second portion of the semiconductor device). In an example, act 1004 comprises performing one or more laser shots on the first surface 122 of the metal silicide layer 120, such as one or more laser shots of an LTA process (e.g., the one or more laser shots may comprise the second plurality of laser shots shown in and/or described with respect to FIGS. 3A-3C).

In some examples, a duration of time between a first time when the first thermal energy 119 is directed to the first surface 114 of the first layer 112 and a second time when the second thermal energy 121 is directed to the first surface 122 of the metal silicide layer 120 is at least a threshold duration of time. In some examples, the threshold duration of time is based upon (e.g., larger than or equal to) a solidification time of melted metal (e.g., metal melted by the first thermal energy 119).

In some examples, after performing act 1003 and prior to performing act 1004, the first surface 122 of the metal silicide layer 120 has a first surface roughness. In some examples, after act 1004 is performed, the first surface 122 of the metal silicide layer 120 has a second surface roughness. The second surface roughness is lower than the first surface roughness (e.g., performing act 1004 reduces the surface roughness of the first surface 122). For example, performing act 1004 smoothens the first surface 122 of the metal silicide layer 120.

Alternatively and/or additionally, after performing act 1003 and prior to performing act 1004, the first surface 122 of the metal silicide layer 120 may have a first quantity of protrusions. In some examples, after act 1004 is performed, the first surface 122 of the metal silicide layer 120 has a second quantity of protrusions. The second quantity of protrusions may be less than the first quantity of protrusions (e.g., performing act 1004 reduces the quantity of protrusions of the first surface 122). Alternatively and/or additionally, protrusions of the first surface 122 of the metal silicide layer 120 prior to performing the act 1004 may be larger and/or taller as compared to protrusions of the first surface 122 after performing act 1004 (e.g., performing act 1004 reduces size and/or height of protrusions of the first surface 122).

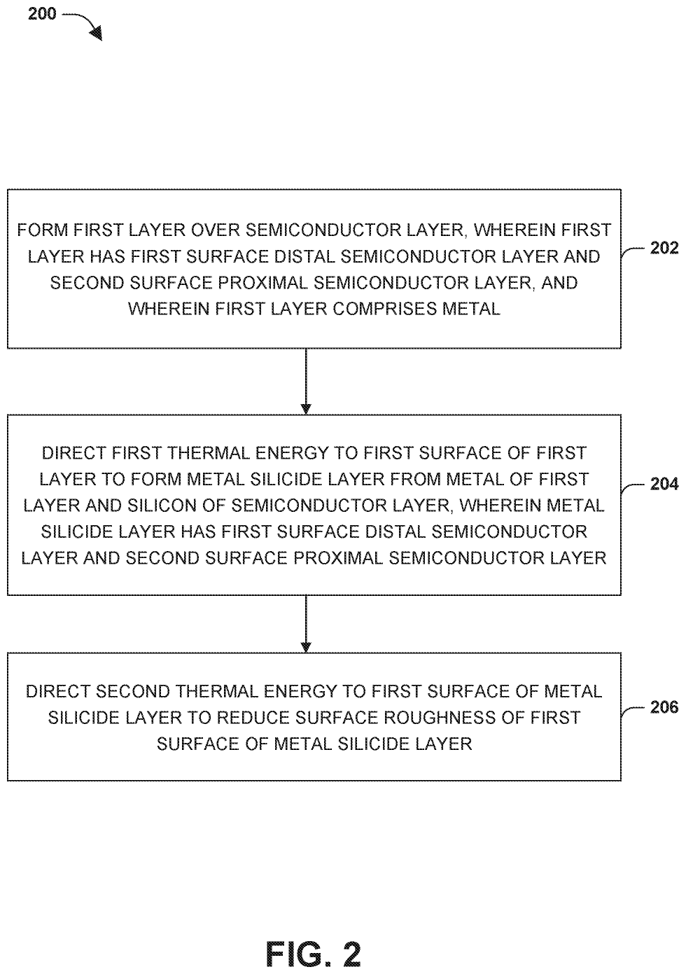

FIG. 2 is an illustration of an example method 200 for manufacturing a semiconductor device. At 202, a first layer (e.g., the first layer 112) is formed over a semiconductor layer (e.g., the semiconductor layer 102, such as a SiC layer). The first layer has a first surface (e.g., the first surface 114) distal the semiconductor layer and a second surface (e.g., the second surface 116) proximal the semiconductor layer. The first layer comprises a metal. At 204, first thermal energy (e.g., the first thermal energy 119) is directed to the first surface of the first layer to form a metal silicide layer (e.g., the metal silicide layer 120) from the metal of the first layer and silicon of the semiconductor layer. The metal silicide layer has a first surface (e.g., the first surface 122) distal the semiconductor layer and a second surface (e.g., the second surface 124) proximal the semiconductor layer. At 206, second thermal energy (e.g., the second thermal energy 121) is directed to the first surface of the metal silicide layer to reduce a surface roughness of the first surface of the metal silicide layer.

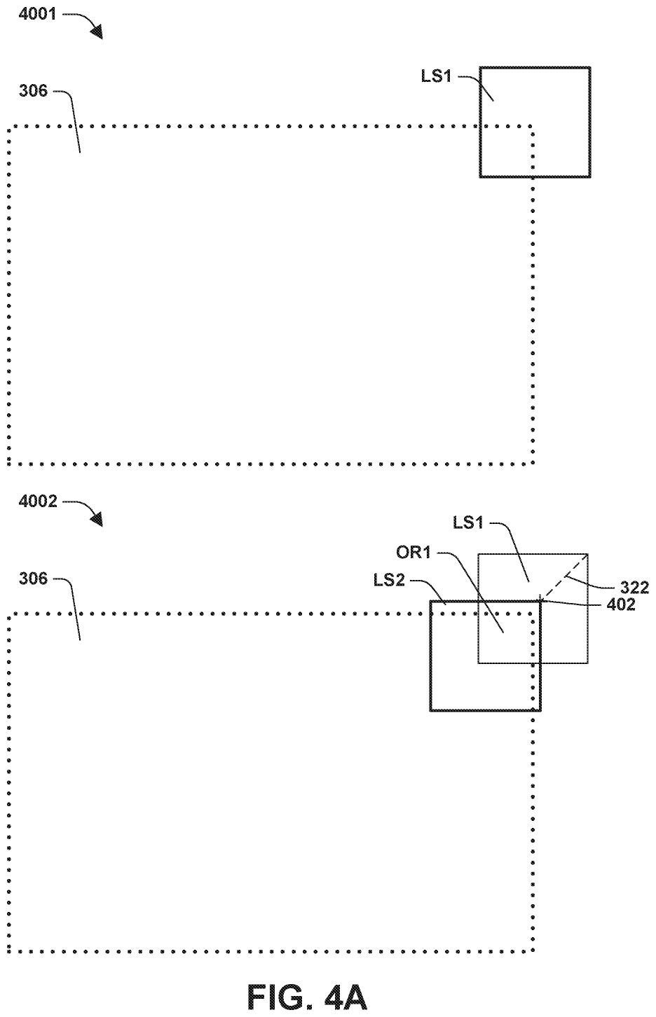

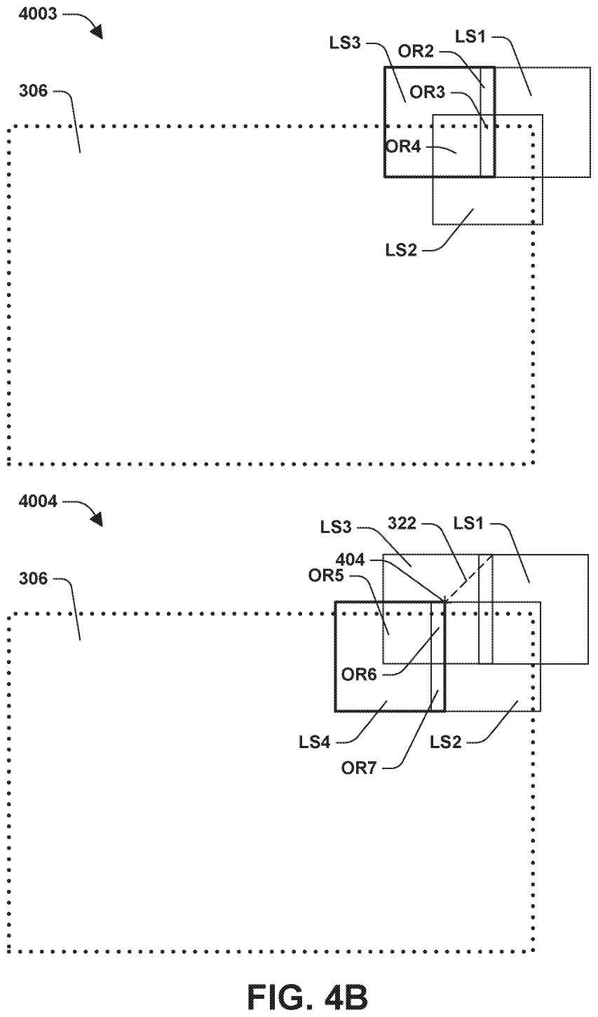

FIGS. 3A-3C and 4A-4B illustrate aspects with respect to performing a plurality of laser shots on a top surface 306 of a first layer (e.g., the first layer 112) to form a metal silicide layer (e.g., the metal silicide layer 120) from metal of the first layer and silicon of a semiconductor layer (e.g., the semiconductor layer 102) underlying the first layer. In an example, the top surface 306 of the first layer corresponds to the first surface 114 of the first layer 112 shown in FIG. 1B. In an example, the top surface 306 of the first layer corresponds to the portion 126 of the first surface 114 of the first layer 112 shown in FIG. 1C (e.g., the top surface 306 corresponds to a top surface of the contact formation region 127 of the first layer 112). A laser shot of the plurality of laser shots comprises illuminating a section of the top surface 306 with a laser pulse. Each section of the top surface 306 is illuminated via at least two laser shots of the plurality of laser shots.

FIGS. 3A-3C illustrate a first example of performing the plurality of laser shots. Example boundaries of the top surface 306 of the first layer are shown with a dotted-line box. The plurality of laser shots may comprise a first plurality of laser shots (described with respect to acts 3001-3003 of FIGS. 3A-3B, for example) and a second plurality of laser shots (described with respect to acts 3004-3005 of FIGS. 3B-3C, for example). In some examples, the first plurality of laser shots is performed in a first LTA process that is performed to illuminate (e.g., irradiate) the top surface 306 (e.g., the entirety of the top surface 306) at least once. For example, metal, of the first layer, across the top surface 306 of the first layer may be melted at least one time during the first LTA process.

At 3001 (shown in FIG. 3A), a first laser shot of the first plurality of laser shots illuminates (e.g., irradiates) an illumination area LS1, comprising a portion of the top surface 306, with a laser pulse. For example, the first laser shot may be performed using a laser source. The first laser shot causes metal, of the first layer, within the illumination area LS1 to melt to form melted metal. In some examples, a width 302 of the illumination area LS1 is between at least 10 millimeters and at most 20 millimeters, such as about 15 millimeters. In some examples, a length 304 of the illumination area LS1 is between at least 10 millimeters and at most 20 millimeters, such as about 15 millimeters. In some examples, the width 302 is about the same as the length 304. In some examples, a size of the illumination area LS1 depends upon the laser source, such as a power capacity of laser shots by the laser source. For example, the size may be a function of the power capacity, where the size may increase with an increase of the power capacity.

At 3002 (shown in FIG. 3A), a second laser shot illuminates an illumination area LS2, comprising a portion of the top surface 306, with a laser pulse. In some examples, the illumination area LS2 overlaps with the illumination area LS1 at an overlapping region OR1. In some examples, the second laser shot is performed such that the illumination area LS2 overlaps with the illumination area LS1 in order to ensure that each section of the top surface 306 is illuminated via a laser shot (e.g., such that an area between the illumination area LS1 and the illumination area LS2 does not stay un-annealed throughout the first plurality of laser shots). Accordingly, a section of the top surface 306 within the overlapping region OR1 is illuminated via two laser shots (e.g., the first laser shot and the second laser shot).

In some examples, a wafer comprising the first layer is set upon a wafer stage that controls a position of the wafer. For example, between the first laser shot (e.g., act 3001) and the second laser shot (e.g., act 3002), a position of the wafer and/or the wafer stage is changed from a first position (e.g., a position of the wafer and/or the wafer stage when the first laser shot is performed) to a second position (e.g., a position of the wafer and/or the wafer stage when the second laser shot is performed) such that the illumination area LS2 (illuminated by the laser pulse output by the laser source) is offset from the illumination area LS1 and/or such that the illumination area LS2 overlaps with the illumination area LS1 at the overlapping region OR1. In some examples, the position of the wafer and/or the wafer stage is changed from the first position to the second position using a motor (e.g., a stepper motor) that controls a position of the wafer stage.

At 3003 (shown in FIG. 3B), laser shots of the first plurality of laser shots (e.g., remaining laser shots of the first plurality of laser shots after the first laser shot and the second laser shot) are performed to illuminate other illumination areas (e.g., other than the illumination areas LS1 and LS2) comprising portions of the top surface 306 with laser pulses. In an example, the other illumination areas comprise an illumination area LS3 illuminated by a third laser shot of the first plurality of laser shots, an illumination area LS4 illumination by a fourth laser shot of the first plurality of laser shots, etc. Laser shots of the first plurality of laser shots may be performed sequentially until illumination areas of the first plurality of laser shots cover an area comprising an entirety of the top surface 306. As shown in FIG. 3B, illumination areas of the first plurality of laser shots may cover an entirety of the top surface 306. In some examples, at least a portion of one or more illumination areas of the first plurality of laser shots (e.g., the illumination area LS1, the illumination area LS2, the illumination area LS4, etc.) are outside the top surface 306 to ensure that the entirety of the top surface 306 is illuminated via at least one laser shot of the first plurality of laser shots.

In an example, the illumination area LS2 overlaps with the illumination area LS3 at an overlapping region OR2 (e.g., a section of the top surface 306 within the overlapping region OR2 is illuminated via two laser shots, such as the second laser shot and the third laser shot). The illumination area LS3 may overlap with the illumination area LS4 at an overlapping region OR3 (e.g., a section of the top surface 306 within the overlapping region OR3 is illuminated via two laser shots, such as the third laser shot and the fourth laser shot). The illumination area LS4 may overlap with the illumination area LS1 at an overlapping region OR4 (e.g., a section of the top surface 306 within the overlapping region OR4 is illuminated via two laser shots, such as the fourth laser shot and the first laser shot). At an overlapping region OR5, the illumination area LS1, the illumination area LS2, the illumination area LS3 and the illumination area LS4 may overlap (e.g., a section of the top surface 306 within the overlapping region OR5 is illuminated via four laser shots).

In some examples, protrusions of the first surface may be greater in quantity, size and/or height within overlapping regions (e.g., overlapping regions OR1, OR2, OR3, OR4, OR5, etc.) of illumination areas of the first plurality of laser shots as compared to sections of the top surface 306 that are illuminated via merely a single laser shot of the first plurality of laser shots.

In some examples, the second plurality of laser shots is performed in a second LTA process that is performed to illuminate (e.g., irradiate) the top surface 306 (e.g., the entirety of the top surface 306) at least once. For example, metal, of the first layer, across the top surface 306 of the first layer may be melted at least one time during the second LTA process.

At 3004 (shown in FIG. 3B), a fifth laser shot of the second plurality of laser shots illuminates (e.g., irradiates) an illumination area LS5, comprising a portion of the top surface 306, with a laser pulse. The fifth laser shot melts metal, of the first layer, within the illumination area LS5 to form melted metal. For clarity, in FIG. 3B, the illumination area LS5 is shown with a solid-line box overlaying illumination areas, of the first plurality of laser shots, that are shown with dashed-line boxes. In some examples, as shown in FIG. 3B, the illumination area LS5 is offset 322 from the illumination area LS1. In an example, the offset 322 between the illumination area LS5 and the illumination area LS1 is implemented such that a corner 323 of the illumination area LS5 is at a point within the illumination area LS1, such as at about a center point of the illumination area LS1. In some examples, illumination areas of the second plurality of laser shots may be offset 322 from illumination areas of the first plurality of laser shots (e.g., each illumination area of the second plurality of laser shots may be offset 322 from an illumination area of the first plurality of laser shots such that a corner of the illumination area of the second plurality of laser points is at a point, such as about a center point, of the illumination area of the first plurality of laser shots).

In an example, the illumination area LS5 overlaps with the illumination area LS1 at an overlapping region OR6 (e.g., a section of the top surface 306 within the overlapping region OR6 is illuminated via two laser shots of the plurality of laser shots). At an overlapping region OR7, the illumination area LS5, the illumination area LS1 and the illumination area LS2 may overlap (e.g., a section of the top surface 306 within the overlapping region OR7 is illuminated via three laser shots of the plurality of laser shots). The illumination area LS5 may overlap with the illumination area LS2 at an overlapping region OR8 (e.g., a section of the top surface 306 within the overlapping region OR8 is illuminated via two laser shots of the plurality of laser shots). At an overlapping region OR9, the illumination area LS5, the illumination area LS2 and the illumination area LS3 may overlap (e.g., a section of the top surface 306 within the overlapping region OR9 is illuminated via three laser shots of the plurality of laser shots). The illumination area LS5 may overlap with the illumination area LS3 at an overlapping region OR10 (e.g., a section of the top surface 306 within the overlapping region OR10 is illuminated via two laser shots of the plurality of laser shots). At an overlapping region OR11, the illumination area LS5, the illumination area LS3 and the illumination area LS4 may overlap (e.g., a section of the top surface 306 within the overlapping region OR11 is illuminated via three laser shots of the plurality of laser shots). The illumination area LS5 may overlap with the illumination area LS4 at an overlapping region OR12 (e.g., a section of the top surface 306 within the overlapping region OR12 is illuminated via two laser shots of the plurality of laser shots). At an overlapping region OR13, the illumination area LS5, the illumination area LS4 and the illumination area LS1 may overlap (e.g., a section of the top surface 306 within the overlapping region OR13 is illuminated via three laser shots of the plurality of laser shots). At an overlapping region OR14, the illumination area LS5, the illumination area LS4, the illumination area LS3, the illumination area LS2, and the illumination area LS1 may overlap (e.g., a section of the top surface 306 within the overlapping region OR14 is illuminated via five laser shots of the plurality of laser shots).

At 3005 (shown in FIG. 3C), laser shots of the second plurality of laser shots (e.g., remaining laser shots of the second plurality of laser shots after the fifth laser shot) are performed to illuminate other illumination areas (e.g., other than the illumination area LS5) comprising portions of the top surface 306 with laser pulses. For clarity, in FIG. 3C, illumination areas, of the second plurality of laser shots, are shown with solid-line boxes and illumination areas, of the first plurality of laser shots, are shown with dashed-line boxes. In some examples, an area comprising illumination areas of the second plurality of laser shots is offset 322 from an area comprising illumination areas of the first plurality of laser shots (e.g., a pattern of the second plurality of laser shots is offset 322 from a pattern of the first plurality of laser shots). Laser shots of the second plurality of laser shots may be performed sequentially until illumination areas of the second plurality of laser shots cover an area comprising an entirety of the top surface 306. As shown in FIG. 3C, illumination areas of the second plurality of laser shots may cover an entirety of the top surface 306. In some examples, at least a portion of some illumination areas of the second plurality of laser shots are outside the top surface 306, thereby ensuring that the entirety of the top surface 306 is illuminated via at least one laser shot of the second plurality of laser shots.

In some examples, implementing the offset 322 between illumination areas of the second plurality of laser shots and illumination areas of the second plurality of laser shots provides for laser shots being more evenly applied to sections of the top surface. For example, by implementing the offset 322, the plurality of laser shots may be performed such that at least one of one or more sections of the top surface 306 are illuminated via two laser shots of the plurality of laser shots (e.g., the one or more sections of the top surface 306 that are illuminated via two laser shots may be within at least one of overlapping regions OR6, OR8, OR10, OR12, etc.), one or more sections of the top surface 306 are illuminated via three laser shots of the plurality of laser shots (e.g., the one or more sections of the top surface 306 that are illuminated via three laser shots may be within at least one of overlapping regions OR7, OR9, OR11, OR13, etc.), and/or one or more sections of the top surface 306 are illuminated via five laser shots of the plurality of laser shots (e.g., the one or more sections of the top surface 306 that are illuminated via five laser shots may be within overlapping region OR14 and/or other overlapping regions). Accordingly, by implementing the offset 322, a difference between a maximum quantity of laser shots (e.g., five) applied to a single section of the top surface 306 and a minimum quantity of laser shots (e.g., two) applied to a single section of the top surface 306 may be three. However, in a scenario in which the offset 322 is not implemented, such as a scenario in which illumination areas of the second plurality of laser shots match illumination areas of the first plurality of laser shots, one or more sections of the top surface 306 may be illuminated via two laser shots of the plurality of laser shots, one or more sections of the top surface 306 may be illuminated via four laser shots of the plurality of laser shots, and/or one or more sections of the top surface 306 may be illuminated via eight laser shots of the plurality of laser shots. Accordingly, without implementing the offset 322, a difference between a maximum quantity of laser shots (e.g., eight) applied to a single section of the top surface 306 and a minimum quantity of laser shots (e.g., two) applied to a single section of the top surface 306 may be six. The lower difference achieved by implementing the offset 322 may provide for lower surface roughness and/or smaller and/or shorter protrusions of the metal silicide layer formed by performing the plurality of laser shots. It may be appreciated that embodiments are contemplated in which illumination areas of the second plurality of laser shots match illumination areas of the first plurality of laser shots (such as where each illumination area of the second plurality of laser shots is about the same as an illumination area of the first plurality of laser shots).

In some examples, laser shots of the plurality of laser shots may be performed based upon the threshold duration of time. For example, a first laser shot with a first illumination area that overlaps with a second illumination area of a second laser shot, preceding the first laser shot, may be performed upon or after the threshold duration of time has passed since a time at which the second laser shot was performed. In an example, the fifth laser shot associated with the illumination area LS5 may be performed at a first time, wherein the first time may be based upon times at which one or more laser shots associated with illumination areas overlapping with the illumination area LS5 are performed. For example, the one or more laser shots may comprise the first laser shot associated with the illumination area LS1, the second laser shot associated with the illumination area LS2, the third laser shot associated with the illumination area LS3, and the fourth laser shot associated with the illumination area LS5. A duration of time between the first time and times at which the one or more laser shots are performed may be equal to or may be larger than the threshold duration of time. Accordingly, in an example in which the threshold duration of time is equal to or larger than the solidification time, metal of the first layer, within the illumination area LS5, is melted via the one or more laser shots, wherein the melted metal solidifies prior to the fifth laser shot being performed on the illumination area LS5.

FIGS. 4A-4B illustrate a second example of performing the plurality of laser shots. Example boundaries of the top surface 306 of the first layer are shown with a dotted-line box. At 4001 (shown in FIG. 4A), a first laser shot of the plurality of laser shots illuminates (e.g., irradiates) an illumination area LS1, comprising a portion of the top surface 306, with a laser pulse. At 4002 (shown in FIG. 4A), a second laser shot of the plurality of laser shots illuminates an illumination area LS2, comprising a portion of the top surface 306, with a laser pulse. Comparing with the first example of performing the plurality of laser shots shown in FIGS. 3A-3C, the second laser shot in the second example (shown in and/or described with respect to FIGS. 4A-4B) may correspond to a laser shot of the second plurality of laser shots in the first example (e.g., the illumination area LS2 of the second laser shot may match the illumination area LS5 of the fifth laser shot of the second plurality of laser shots), whereas, in the second example, the second laser shot may be performed prior to completion of the first plurality of laser shots. In some examples, the illumination area LS2 is offset 322 from the illumination area LS1. In an example, the offset 322 between the illumination area LS2 and the illumination area LS1 is implemented such that a corner 402 of the illumination area LS2 is at a point within the illumination area LS1, such as at about a center point of the illumination area LS1. The illumination area LS2 may overlap with the illumination area LS1 at overlapping region OR1. In some examples, a duration of time between the first laser shot and the second laser shot is equal to or larger than the threshold duration of time.

At 4003 (shown in FIG. 4B), a third laser shot of the plurality of laser shots illuminates (e.g., irradiates) an illumination area LS3, comprising a portion of the top surface 306, with a laser pulse. The illumination area LS3 may overlap with the illumination area LS1 and/or the illumination area LS2 at overlapping regions OR2, OR3 and/or OR4. In some examples, a duration of time between the second laser shot and the third laser shot is equal to or larger than the threshold duration of time.

At 4004 (shown in FIG. 4B), a fourth laser shot of the plurality of laser shots illuminates (e.g., irradiates) an illumination area LS4, comprising a portion of the top surface 306, with a laser pulse. In some examples, a duration of time between the third laser shot and the fourth laser shot is equal to or larger than the threshold duration of time. In some examples, the illumination area LS4 is offset 322 from the illumination area LS3. In an example, the offset 322 between the illumination area LS4 and the illumination area LS3 is implemented such that a corner 404 of the illumination area LS4 is at a point within the illumination area LS3, such as at about a center point of the illumination area LS3. The illumination area LS4 may overlap with the illumination area LS2 and/or the illumination area LS3 at overlapping regions OR5, OR6 and/or OR7. In some examples, a duration of time between the third laser shot and the fourth laser shot is equal to or larger than the threshold duration of time.

In some examples, after the fourth laser shot is performed, remaining laser shots of the plurality of laser shots are performed (e.g., laser shots of the plurality of laser shots are performed until illumination areas of the plurality of laser shots cover an area comprising an entirety of the top surface 306 and/or each section of the top surface 306 is illuminated via at least two laser shots of the plurality of laser shots). In an example, illumination areas of the plurality of laser shots may have the arrangement of illumination areas shown in FIG. 3C.

In some examples, an order in which laser shots of the plurality of laser shots are performed may be different than the example orders shown in and/or described with respect to FIGS. 3A-3C and/or FIGS. 4A-4B.

In some examples, by performing the plurality of laser shots according to one or more of the techniques provided herein (e.g., shown in and/or described with respect to FIGS. 3A-4B and/or FIGS. 4A-4B), a top surface of the metal silicide layer (e.g., the metal silicide layer 120) formed from metal of the first layer and silicon of the semiconductor layer may have a top surface (e.g., the first surface 122) that has a lower surface roughness (and/or reduced quantity of protrusions and/or smaller and/or shorter protrusions) as compared to a metal silicide layer that is formed without using one or more of the techniques provided herein. For example, the lower surface roughness (and/or the reduced quantity of protrusions and/or the smaller and/or shorter protrusions) may be a result of performing the plurality of laser shots such that each section of the top surface 306 is illuminated by at least two laser shots (rather than sections of the top surface 306 being illuminated by merely one laser shot, for example).

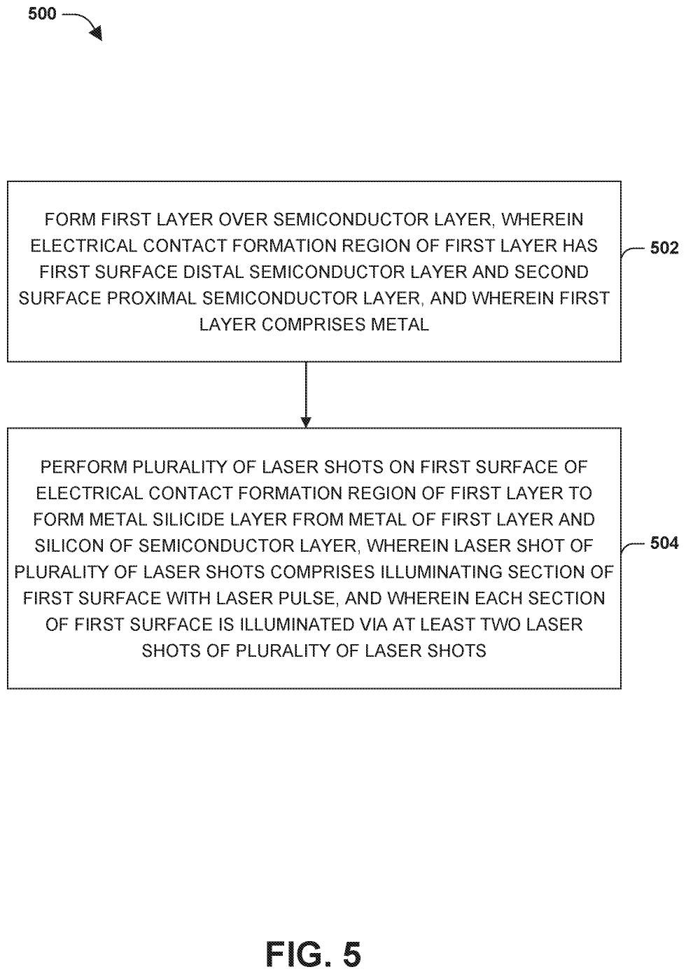

FIG. 5 is an illustration of an example method 500 for manufacturing a semiconductor device. At 502, a first layer (e.g., the first layer 112) is formed over a semiconductor layer (e.g., the semiconductor layer 102, such as a SiC layer). An electrical contact formation region of the first layer has a first surface (e.g., the top surface 306) distal the semiconductor layer and a second surface proximal the semiconductor layer. In some examples, the electrical contact formation region comprises an entirety of the first layer (e.g., the first surface corresponds to the first surface 114 of the first layer 112). In some examples, the electrical contact formation region comprises a portion of the first layer (e.g., the first surface corresponds to the portion 126 of the first surface 114 of the first layer 112 shown in FIG. 1C). The first layer comprises a metal. At 504, a plurality of laser shots (e.g., the plurality of laser shots shown in and/or described with respect to FIGS. 3A-3C and/or FIGS. 4A-4B) is performed on the first surface of the electrical contact formation region of the first layer to form a metal silicide layer (e.g., the metal silicide layer 120) from the metal of the first layer and silicon of the semiconductor layer. A laser shot of the plurality of laser shots comprises illuminating a section of the first surface with a laser pulse. Each section of the first surface is illuminated via at least two laser shots of the plurality of laser shots.

FIG. 6 illustrates aspects with respect to manufacturing a semiconductor device according to various examples of the present disclosure. At 6001, a semiconductor structure comprising the semiconductor layer 102 and a metal silicide layer 602 is provided. The metal silicide layer 602 may be formed using one or more of the techniques provided herein, such as shown in and/or described with respect to FIGS. 1A-1E, FIG. 2, FIGS. 3A-3C, FIGS. 4A-4B and/or FIG. 5. For example, the metal silicide layer 602 may be formed to have a surface 604 with a reduced surface roughness compared to a second metal silicide layer formed without using one or more of the techniques herein to form the metal silicide layer. In an example, the second metal silicide layer may be formed with an LTA process that illuminates at least some sections of surface of a layer with merely one laser pulse. A surface of the second metal silicide layer may have protrusions with local elevations up to about 400 nanometers, and/or even up to about 1000 nanometers. However, the surface 604 of the metal silicide layer 602 formed using one or more of the techniques provided herein may have less protrusions than the surface of the second metal silicide layer and/or protrusions of the surface 604 of the metal silicide layer 602 may have a maximum local elevation of about 140 nanometers.

At 6002, one or more metal layers 606 are formed over the metal silicide layer 602. For example, the one or more metal layers 606 may be formed in a back side metal (BSM) process. In some examples, the one or more metal layers 606 may be in contact (e.g., direct contact) with the surface 604 of the metal silicide layer 602. In an example, the metal silicide layer 602 forms an electrical contact (e.g., an Ohmic contact) between the one or more metal layers 606 and the semiconductor layer 102. In some examples, a metal layer of the one or more metal layers 606 may be formed via a sputtering process, an evaporation deposition process, and/or one or more other deposition processes.

In some examples, the reduced surface roughness of the surface 604 of the metal silicide layer 602 results in a reduced surface roughness of a surface 608 of the one or more metal layers 606. In an example, the surface 608 of the one or more metal layers 606 may correspond to a top surface of a top-most metal layer of the one or more metal layers 606. In some examples, the surface 608 corresponds to a back side of a wafer comprising the semiconductor layer 102, the metal silicide layer 602 and/or the one or more metal layers 606. In some examples, as a result of forming the metal silicide layer 602 using one or more of the techniques provided herein, the surface 608 of the one or more metal layers 606 may have the reduced surface roughness and/or may have a reduced quantity of protrusions and/or a reduced size and/or height of protrusions.

In some examples, one or more acts may be performed after act 6001 and/or prior to act 6002. In some examples, the one or more acts comprise removing carbon from the metal silicide layer 602 (such as removing carbon on the surface 604) using one or more liquids and/or gases. In an example, oxygen plasma may be applied to the surface 604 (by performing an O₂ flash, for example) to remove the carbon. In some examples, the one or more acts comprise removing oxide from the metal silicide layer 602 (such as removing oxide from the surface 604) using one or more liquids and/or one or more gases, such as using one or more etching chemicals (e.g., hydrofluoric acid and/or one or more other etching chemicals). In an example, the oxide may comprise metal oxide (e.g., nickel oxide in a scenario in which the metal silicide layer 602 is formed from a layer comprising nickel) and/or silicon oxide (e.g., the oxide may be formed as a result of applying the oxygen plasma to the surface 604).

At 6003, the wafer is affixed to a lead frame 610. In some examples, the top-most metal layer of the one or more metal layers 606 having the surface 608 is affixed to the lead frame 610. For example, the surface 608 of the top-most metal layer of the one or more metal layers 606 may be soldered to the lead frame 610, wherein the top-most metal layer may have a thickness that is larger than one, some and/or all other metal layers of the one or more metal layers 606. In some examples, there may be fewer and/or smaller voids between the surface 608 of the metal layer and the lead frame 610, such as due to the surface 608 having the reduced surface roughness and/or due to the surface 608 having the reduced quantity of protrusions and/or the reduced size and/or height of protrusions. The fewer and/or smaller voids may provide for an improved electrical connection between the one or more metal layers 606 and the lead frame 610, which may provide for improved operation and/or performance a system comprising the wafer.

In some examples, the wafer may undergo a wafer testing process (e.g., the wafer testing process may be performed on the wafer prior to act 6003). In the wafer testing process, the surface 608 may be in contact (e.g., direct contact) with a measuring chuck that is configured to measure a current from the one or more metal layers 606. The surface 608 having the reduced surface roughness and/or the surface 608 having the reduced quantity of protrusions and/or the reduced size and/or height of protrusions may result in improved contact between the measuring chuck and the surface 608 (i.e., increased conductivity between the one or more metal layers 606 and the measuring chuck) such that current measurements (e.g., current measurements) in the wafer testing process are performed more accurately.

Alternatively and/or additionally, the wafer comprising the metal silicide layer 602 may have an improved VF (forward biased junction voltage) distribution and/or improved VF values as compared to other wafers with metal silicide layers (e.g., the second metal silicide layer) formed without using one or more of the techniques provided herein.

Some semiconductor devices formed without one or more of the techniques provided herein are formed with thicker metal layers in an attempt to bury protrusions of a surface of a metal silicide layer. It may be appreciated that implementing one or more of the techniques provided herein enables the one or more metal layers 606 to be formed with reduced thicknesses, such as due to the surface 608 having the reduced surface roughness and/or due to the surface 608 having the reduced quantity of protrusions and/or the reduced size and/or height of protrusions. The reduced thicknesses of the one or more metal layers 606 may provide for lower material costs and/or a smaller size of the semiconductor device.

It may be appreciated that some techniques typically used for surface smoothing of semiconductors, such as chemical-mechanical polishing and/or planarization (CMP), if performed on the metal silicide layer 602, may result in damaging the metal silicide layer 602 and/or do not smoothen the metal silicide layer 602. For example, performing CMP on the metal silicide layer 602 to smoothen the metal silicide layer 602 may damage the metal silicide layer 602 and/or remove portions of the metal silicide layer 602, thereby resulting in formation of an electrical contact (e.g., Ohmic contact) that does not function correctly.

According to some embodiments, a method for manufacturing a semiconductor device is provided. The method comprises forming a first layer over a SiC layer, wherein the first layer has a first surface distal the SiC layer and a second surface proximal the SiC layer, and wherein the first layer comprises a metal; directing first thermal energy to the first surface of the first layer to form a metal silicide layer from the metal of the first layer and silicon of the SiC layer, wherein the metal silicide layer has a first surface distal the SiC layer and a second surface proximal the SiC layer; and directing second thermal energy to the first surface of the metal silicide layer to reduce a surface roughness of the first surface of the metal silicide layer.

According to some embodiments, a duration of time between a first time when the first thermal energy is directed to the first surface of the first layer and a second time when the second thermal energy is directed to the first surface of the metal silicide layer is at least a threshold duration of time.

According to some embodiments, the first thermal energy directed to the first surface of the first layer melts metal of the first layer to form melted metal, the threshold duration of time is based upon a solidification time of the melted metal, and the melted metal solidifies prior to the second time.

According to some embodiments, the method comprises, after directing the second thermal energy to the first surface of the metal silicide layer, forming one or more metal layers over the metal silicide layer.

According to some embodiments, the method comprises affixing a layer of the one or more metal layers to a lead frame.

According to some embodiments, the metal comprises nickel.

According to some embodiments, the first layer is formed to have a thickness less than 200 nanometers.

According to some embodiments, a method for manufacturing a semiconductor device is provided. The method comprises forming a first layer over a SiC layer, wherein an electrical contact formation region of the first layer has a first surface distal the SiC layer and a second surface proximal the SiC layer, and wherein the first layer comprises a metal; and performing a plurality of laser shots on the first surface of the electrical contact formation region of the first layer to form a metal silicide layer from the metal of the first layer and silicon of the SiC layer, wherein a laser shot of the plurality of laser shots comprises illuminating a section of the first surface with a laser pulse, and wherein each section of the first surface is illuminated via at least two laser shots of the plurality of laser shots.

According to some embodiments, the plurality of laser shots comprise a first laser shot and a second laser shot, the first laser shot comprises illuminating a first section of the first surface with a first laser pulse, the second laser shot comprises illuminating the first section of the first surface with a second laser pulse, and a duration of time between the first laser shot and the second laser shot is at least a threshold duration of time.

According to some embodiments, the first laser shot melts metal of the first layer to form melted metal, the threshold duration of time is based upon a solidification time of the melted metal, and the melted metal solidifies prior to the second laser shot.

According to some embodiments, after the first laser shot and prior to the second laser shot, the first section of the first surface has a first surface roughness, and after the second laser shot, the first section of the first surface has a second surface roughness less than the first surface roughness.

According to some embodiments, a second section of the first surface, comprising the first section of the first surface, is illuminated with the first laser pulse, a third section of the first surface, comprising the first section of the first surface, is illuminated with the second laser pulse, the third section of the first surface is offset from the second section of the first surface, and the third section and the second section overlap at the first section.

According to some embodiments, the method comprises, after performing the plurality of laser shots, forming one or more metal layers over the metal silicide layer; and affixing a layer of the one or more metal layers to a lead frame.

According to some embodiments, the first layer comprises silicon.

According to some embodiments, the metal comprises nickel.

According to some embodiments, the first layer is formed to have a thickness less than 200 nanometers.

According to some embodiments, a semiconductor device is provided. The semiconductor device comprises a SiC layer; a metal silicide layer over the SiC layer, wherein the metal silicide layer has a first surface distal the SiC layer and a second surface proximal the SiC layer, and wherein a surface roughness of the first surface is at most 200 nanometers; and one or more metal layers over the metal silicide layer.

According to some embodiments, a thickness of the metal silicide layer is less than 300 nanometers.

According to some embodiments, the metal silicide layer comprises nickel.

According to some embodiments, a layer of the one or more metal layers is affixed to a lead frame.

It may be appreciated that combinations of one or more embodiments described herein, including combinations of embodiments described with respect to different figures, are contemplated herein.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A method of manufacturing a semiconductor device, comprising:
forming a first layer over a silicon carbide (SiC) layer, wherein:
the first layer has a first surface distal the SiC layer and a second surface proximal the SiC layer, and
the first layer comprises a metal;
directing first thermal energy to the first surface of the first layer to form a metal silicide layer from the metal of the first layer and silicon of the SiC layer, wherein the metal silicide layer has a first surface distal the SiC layer and a second surface proximal the SiC layer; and
directing second thermal energy to the first surface of the metal silicide layer to reduce a surface roughness of the first surface of the metal silicide layer.

2. The method of claim 1, wherein:
a duration of time between a first time when the first thermal energy is directed to the first surface of the first layer and a second time when the second thermal energy is directed to the first surface of the metal silicide layer is at least a threshold duration of time.

3. The method of claim 2, wherein:
the first thermal energy directed to the first surface of the first layer melts metal of the first layer to form melted metal,
the threshold duration of time is based upon a solidification time of the melted metal, and
the melted metal solidifies prior to the second time.

4. The method of claim 1, comprising:
after directing the second thermal energy to the first surface of the metal silicide layer, forming one or more metal layers over the metal silicide layer.

5. The method of claim 4, comprising:
affixing a layer of the one or more metal layers to a lead frame.

6. The method of claim 1, wherein:
the metal comprises nickel.

7. The method of claim 1, wherein:
the first layer is formed to have a thickness less than 200 nanometers.

8. A method of manufacturing a semiconductor device, comprising:
forming a first layer over a silicon carbide (SiC) layer, wherein:
an electrical contact formation region of the first layer has a first surface distal the SiC layer and a second surface proximal the SiC layer, and
the first layer comprises a metal; and
performing a plurality of laser shots on the first surface of the electrical contact formation region of the first layer to form a metal silicide layer from the metal of the first layer and silicon of the SiC layer, wherein:
a laser shot of the plurality of laser shots comprises illuminating a section of the first surface with a laser pulse, and
each section of the first surface is illuminated via at least two laser shots of the plurality of laser shots.

9. The method of claim 8, wherein:
the plurality of laser shots comprise a first laser shot and a second laser shot,
the first laser shot comprises illuminating a first section of the first surface with a first laser pulse,
the second laser shot comprises illuminating the first section of the first surface with a second laser pulse, and
a duration of time between the first laser shot and the second laser shot is at least a threshold duration of time.

10. The method of claim 9, wherein:
the first laser shot melts metal of the first layer to form melted metal,
the threshold duration of time is based upon a solidification time of the melted metal, and
the melted metal solidifies prior to the second laser shot.

11. The method of claim 9, wherein:
after the first laser shot and prior to the second laser shot, the first section of the first surface has a first surface roughness, and
after the second laser shot, the first section of the first surface has a second surface roughness less than the first surface roughness.

12. The method of claim 9, wherein:
a second section of the first surface, comprising the first section of the first surface, is illuminated with the first laser pulse,
a third section of the first surface, comprising the first section of the first surface, is illuminated with the second laser pulse,
the third section of the first surface is offset from the second section of the first surface, and
the third section and the second section overlap at the first section.

13. The method of claim 8, comprising:
after performing the plurality of laser shots, forming one or more metal layers over the metal silicide layer; and
affixing a layer of the one or more metal layers to a lead frame.

14. The method of claim 8, wherein:
the first layer comprises silicon.

15. The method of claim 8, wherein:
the metal comprises nickel.

16. The method of claim 8, wherein:
the first layer is formed to have a thickness less than 200 nanometers.

17. A semiconductor device, comprising:
a silicon carbide (SiC) layer;
a metal silicide layer over the SiC layer, wherein:
the metal silicide layer has a first surface distal the SiC layer and a second surface proximal the SiC layer, and
a surface roughness of the first surface is at most 200 nanometers; and
one or more metal layers over the metal silicide layer.

18. The semiconductor device of claim 17, wherein:
a thickness of the metal silicide layer is less than 300 nanometers.

19. The semiconductor device of claim 17, wherein:
the metal silicide layer comprises nickel.

20. The semiconductor device of claim 17, wherein:
a layer of the one or more metal layers is affixed to a lead frame.
